(19) United States
(12) Patent Application Publication
(10) Pub. No.: US 2016/0273109 A1
(43) Pub. Date: Sep. 22, 2016

(54) SEMICONDUCTOR MANUFACTURING APPARATUS AND METHOD FOR MANUFACTURING SEMICONDUCTOR DEVICE

(71) Applicant: Kabushiki Kaisha Toshiba, Tokyo (JP)

(72) Inventors: Yoshiyuki Harada, Nonoichi Ishikawa (JP); Kotaro Zaima, Nomi Ishikawa (JP); Hidenori Hanyu, Kanazawa Ishikawa (JP); Takashi Kataoka, Himeji Hyogo (JP)

(21) Appl. No.: 14/840,734

(22) Filed: Aug. 31, 2015

(30) Foreign Application Priority Data
Mar. 16, 2015 (JP) 2015-052741

(51) Int. Cl. C23C 16/455; H01L 21/02

(52) U.S. Cl. CPC C23C 16/45572; H01L 21/0254; H01L 21/02576; C23C 16/45565

(57) ABSTRACT

According to one embodiment, a semiconductor manufacturing apparatus includes a cover part, a gas introduction part provided in the cover part, and a shower plate. The shower plate includes a space, a bottom part, and an outer frame part, the space being provided by jointing the shower plate with the cover part, the space being capable of containing a gas introduced from the gas introduction part, the outer frame part surrounding the bottom part, the bottom part including a plurality of ejection ports to eject the gas, a first cooling path being disposed between the ejection ports and the cover part in a center part of the bottom part, and a second cooling path disposed between the ejection ports and the cover part in an outer peripheral part of the bottom part surrounding the center part, the second cooling path being not connected with the first cooling path

### CROSS-REFERENCE TO RELATED APPLICATIONS

This application is based upon and claims the benefit of priority from Japanese Patent Application No. 2015-052741, filed on Mar. 16, 2015; the entire contents of which are incorporated herein by reference.

### FIELD

Embodiments described herein relate generally to a semiconductor manufacturing apparatus and a method for manufacturing a semiconductor device.

### BACKGROUND

As one of semiconductor manufacturing apparatuses, there is a film forming apparatus including a shower head. In the film forming apparatus, for example, the shower head is made to face a substrate disposed in a reduced pressure atmosphere, and a source gas is ejected to the substrate from plural ejection ports provided in the shower head. The substrate is suitably heated by a heating unit. The source gas reacts on the substrate and a thin film is formed.

However, when the temperature distribution of the shower head is non-uniform, the temperature distribution of the source gas ejected from the shower head becomes also non-uniform, and the thickness and the film quality of the thin film formed on the substrate may become non-uniform.

### BRIEF DESCRIPTION OF THE DRAWINGS

FIG. 1A is a schematic sectional view showing a semiconductor manufacturing apparatus of a first embodiment, FIG. 1A shows a cross-section taken along line A1 to A2 in FIG. 1B, and FIG. 1B is a schematic lower surface view showing the semiconductor manufacturing apparatus of the first embodiment;

FIG. 2 is a schematic view showing the semiconductor manufacturing apparatus of the first embodiment;

FIG. 3 is a schematic sectional view of a film forming apparatus including the semiconductor manufacturing apparatus of the first embodiment;

FIG. 4A and FIG. 4B are schematic sectional views showing the operation of the semiconductor manufacturing apparatus of the first embodiment; and

FIG. 5 shows a schematic sectional view of a HEMT.

### DETAILED DESCRIPTION

According to one embodiment, a semiconductor manufacturing apparatus includes a cover part, a gas introduction part provided in the cover part, and a shower plate. The shower plate includes a space, a bottom part, and an outer frame part, the space being provided by jointing the shower plate with the cover part, the space being capable of containing a gas introduced from the gas introduction part, the outer frame part surrounding the bottom part, the bottom part including a plurality of ejection ports to eject the gas, a first cooling path being disposed between the ejection ports and the cover part in a center part of the bottom part, and a second cooling path disposed between the ejection ports and the cover part in an outer peripheral part of the bottom part surrounding the center part, the second cooling path being not connected with the first cooling path.

Hereinafter, embodiments will be described with reference to the drawings. In the following description, the same components are denoted by the same reference numerals, and the description of the component once described is suitably omitted. In the drawings illustrated below, a three-dimensional coordinate is introduced. As axial directions of the three-dimensional coordinate, a first direction (hereinafter, for example, a Z-direction), a second direction (hereinafter, for example, a Y-direction) crossing the Z-direction, and a third direction (hereinafter, for example, an X-direction) crossing the Z-direction and the Y-direction are introduced.

### First Embodiment

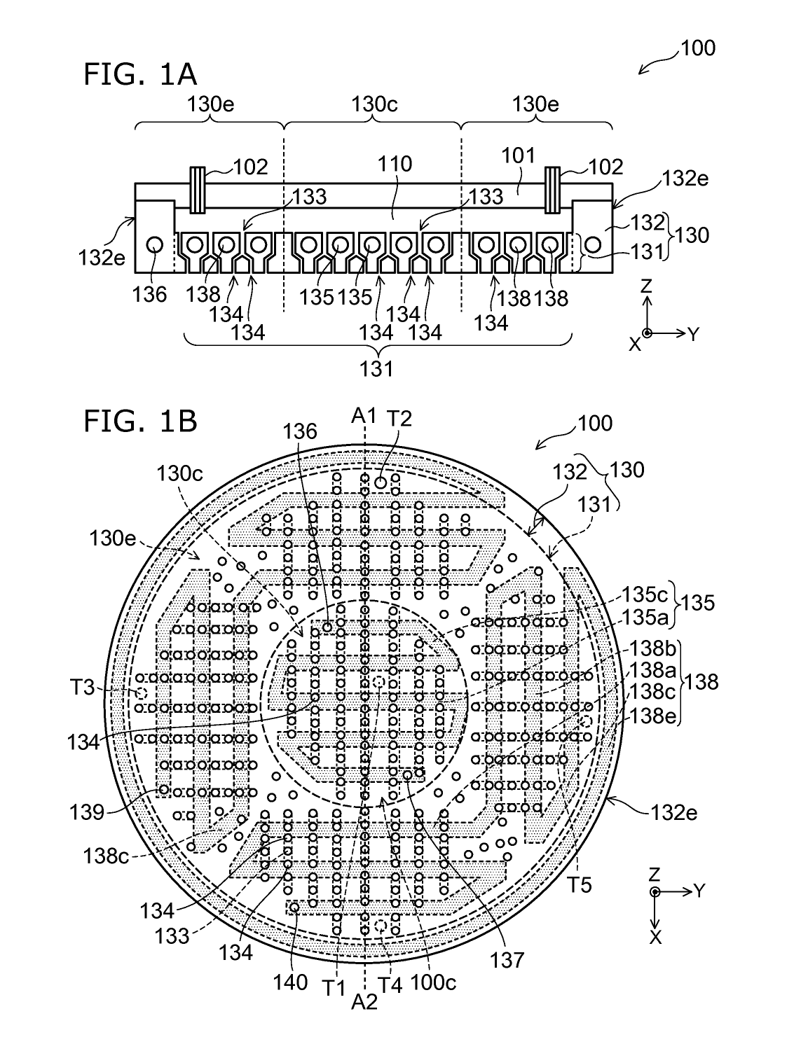

FIG. 1A is a schematic sectional view showing a semiconductor manufacturing apparatus of a first embodiment. FIG. 1A shows a cross-section taken along line A1-A2 of FIG. 1B. FIG. 1B is a schematic lower surface view showing the semiconductor manufacturing apparatus of the first embodiment. FIG. 1A and FIG. 1B show a shower head installed in the semiconductor manufacturing apparatus of the first embodiment.

A shower head 100 shown in FIG. 1A and FIG. 1B is used for, for example, ALD (Atomic Layer Deposition), MLD (Molecular Layer Deposition), CVD (Chemical Vapor Deposition) or the like.

The shower head 100 includes a cover part 101, a gas introduction part 102, and a shower plate 130. In the first embodiment, a direction from a bottom part 131 of the shower plate 130 to the cover plate 101 is the Z-direction.

The gas introduction part 102 is installed in the cover part 101. A source gas for film formation is introduced into a space 110 in the shower head 100 through the gas introduction part 102.

The shower plate 130 includes the bottom part 131 and an outer frame part 132 surrounding the bottom part 131. A plane shape of the bottom part 131 is circular. The shower plate 130 and the cover part 101 are jointed so that the space 110 is formed in the shower head 100. The gas introduced from the gas introduction part 102 is contained in the space 110.

A lower surface (surface at a lower side in FIG. 1A) of the bottom part 131 is provided with plural ejection ports 134 for ejecting the gas temporarily stayed in the space 110. For example, a hole 133 connected to the space 110 is branched into two holes on a lower side. The branched two holes constitute a pair of the ejection ports 134 on the lower surface of the bottom part 131.

On the bottom part 131, a first cooling path 135 and a second cooling path 138 not connected with the first cooling path 135 are provided between the plural ejection ports 134 and the cover part 101. The respective plural ejection ports 134 are arranged along a direction in which the first cooling path 135 extends or a direction in which the second cooling path 138 extends.

The first cooling path 135 is disposed in a center part 130c of the bottom part 131. A planar shape of the center part 130c is circular. The center part 130c and an outer peripheral part 130e are concentrically disposed on the bottom part 131. That is, the center part 130c and the outer peripheral part 130e are partitioned in the direction from the center of the bottom part 131 toward the outer frame part 132. The first cooling path 135 includes plural portions 135a extending in the Y-direction and connecting parts 135c for connecting the plural portions 135a. The first cooling path 135 is, for example, a continuous flow path in the center part 130c. For example, in the center part 130c, a cooling medium introduced from the first introduction port 136 is discharged to a first discharge port 137 through the first cooling path 135 which is bent at plural places.

The second cooling path 138 is disposed in the outer peripheral part 130e surrounding the center part 130c. The outer peripheral part 130e includes the bottom part 131 other than the center part 130c and the outer frame part 132. The second cooling path 138 is disposed in the bottom part 131 outside the center part 130c and the outer frame part 132. That is, the second cooling path 138 may extend to the outer frame part 132.

The second cooling path 138 includes plural portions 138a extending in the Y-direction, connecting parts 138c for connecting the plural portions 138a, plural portions 138b extending in the X-direction, connecting parts 138c for connecting the plural portions 138b, and a portion 138e extending along an outer end 132e of the outer frame part 132. The second cooling path 138 is a continuous flow path in the outer peripheral part 130e. For example, in the outer peripheral part 130e, a cooling medium introduced from a second introduction portion 139 is discharged to a second discharge port 140 through the second cooling path 138 which is bent at plural places.

Furthermore, the shower head 100 is provided with plural temperature detectors T1 to T5. The temperature detectors T1 to T5 are, for example, thermocouples. The temperature detector T1 is disposed substantially at the center of the center part 130c. The temperature detectors T2 to T5 are disposed at every substantially 90° near the outer end 132e of the outer peripheral part 130e.

As stated above, in the shower head 100, the arrangement area of the cooling path is concentrically partitioned into the plural zones. For example, the plural zones are the center part 130c and the outer peripheral part 130e surrounding the center part 130c. Accordingly, the cooling path has two path systems. Incidentally, the plural zones are not limited to two zones. The number of the concentrically partitioned zones may be three or more.

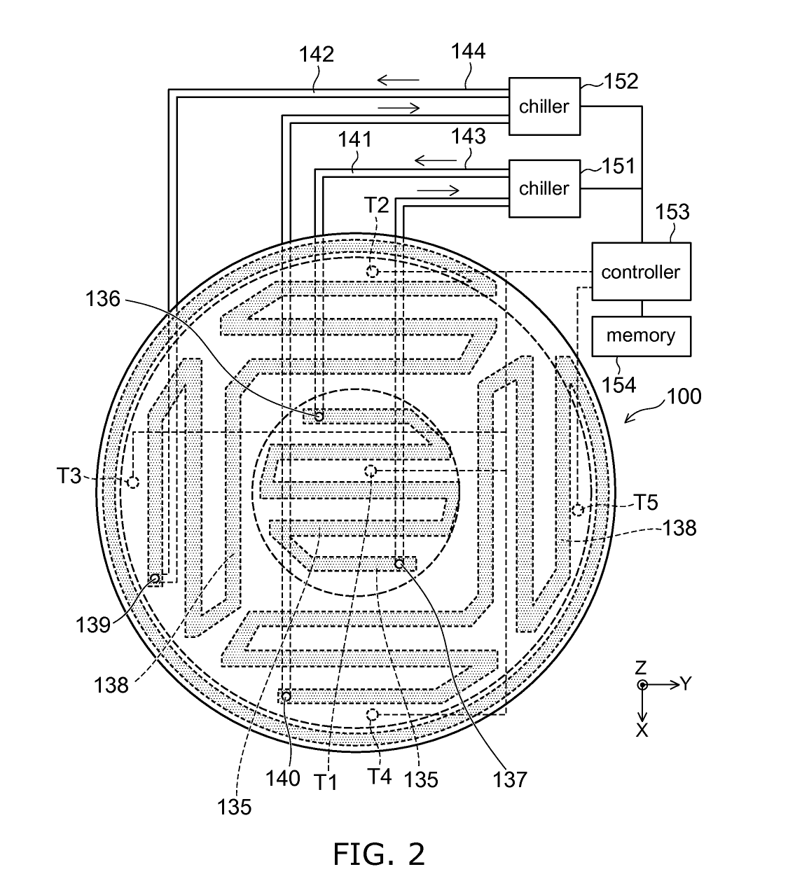

FIG. 2 is a schematic view showing the semiconductor manufacturing apparatus of the first embodiment.

In FIG. 2, the ejection ports 134 of the shower head 100 are not shown.

The shower head 100 is attached with a first supplier (hereinafter, for example, a chiller 151) and a second supplier (hereinafter, for example, a chiller 152). The chiller 151 supplies a first cooling medium 141 to the first cooling path 135 through a pipe 143. The chiller 152 supplies a second cooling medium 142 to the second cooling path 138 through a pipe 144.

The temperatures of the first cooling medium 141 and the second cooling medium 142 are controlled by a controller 153. The respective temperatures of the first cooling medium 141 and the second cooling medium 142 are independently controlled by the controller 153. For example, the control part 153 sets the temperature of the second cooling medium 142 flowing through the second cooling path 138 to be different from the temperature of the first cooling medium 141 flowing through the first cooling path 135.

The temperature detected by each of the temperature detectors T1 to T5 is transferred to the controller 153. The controller 153 can perform feedback control to control the temperature of each of the first cooling medium 141 and the second cooling medium 142 in real time according to the temperature detected by each of the temperature detectors T1 to T5.

Furthermore, the controller 153 can calculate temperature distribution in the shower head 100 by the temperatures detected by the plural temperature detectors T1 to T5. The controller 153 controls the temperature of the first cooling medium 141 or the second cooling medium 142 according to the temperature distribution. Further, the controller 153 calculates temporal changes in the temperature distribution detected by the plural temperature detectors T1 to T5. The information of the temperature distribution and the temporal changes in the temperature distribution is stored in a memory 154.

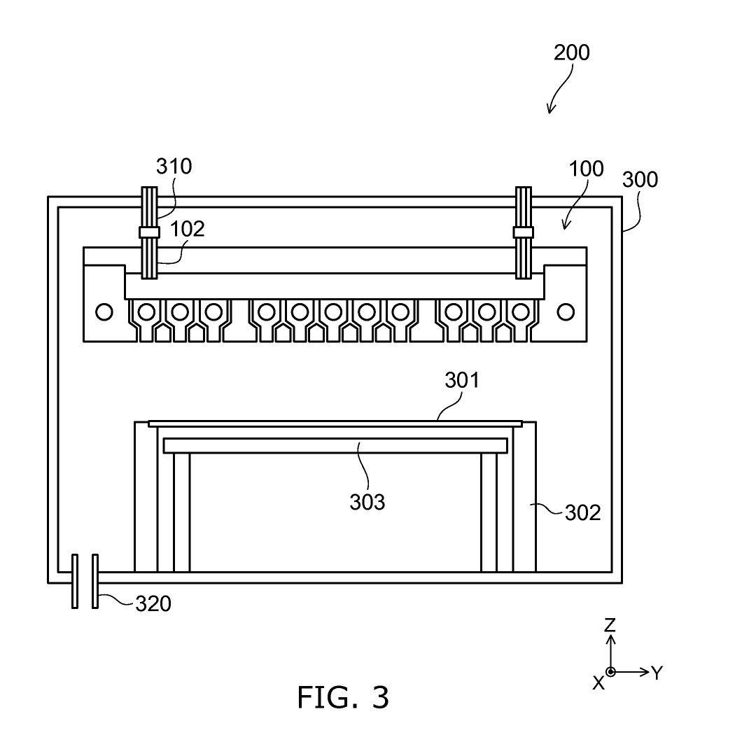

FIG. 3 is a schematic sectional view of a film forming apparatus including the semiconductor manufacturing apparatus of the first embodiment.

A semiconductor manufacturing apparatus 200 of the first embodiment includes a vacuum chamber 300, the shower head 100 described above, a gas exhaust mechanism 320, a susceptor 302, and a heater 303. In addition, the semiconductor manufacturing apparatus 200 includes the chillers 151 and 152, the controller 153, the memory 154, and the pipes 143 and 144, which are illustrated in FIG. 2 (not shown in FIG. 3).

The shower head 100 is installed in the vacuum chamber 300. An atmosphere having a lower pressure than atmospheric pressure can be kept in the vacuum chamber 300 by the gas exhaust mechanism 320. A substrate 301 such as a semiconductor wafer is supported by the susceptor 302. The susceptor 302 is rotatable. When the susceptor 302 rotates, the substrate 301 rotates. The heater 303 to heat the substrate 301 is provided below the substrate 301. The substrate 301 is heated by the heater 303 to, for example, 700° C. to 1500° C.

The shower head 100 in the vacuum chamber 300 is installed to face the substrate 301. The gas introduction part 102 is connected to a gas supply port 310 installed in the vacuum chamber 300. By this, a source gas can be supplied into the shower head 100 from the outside of the vacuum chamber 300 through the gas supply port 310 and the gas introduction part 102. When the source gas is ejected to the substrate 301 from the plural ejection ports 134, for example, a chemical reaction occurs on the substrate 301 heated to a specified temperature. By this, a thin film is formed on the substrate 301.

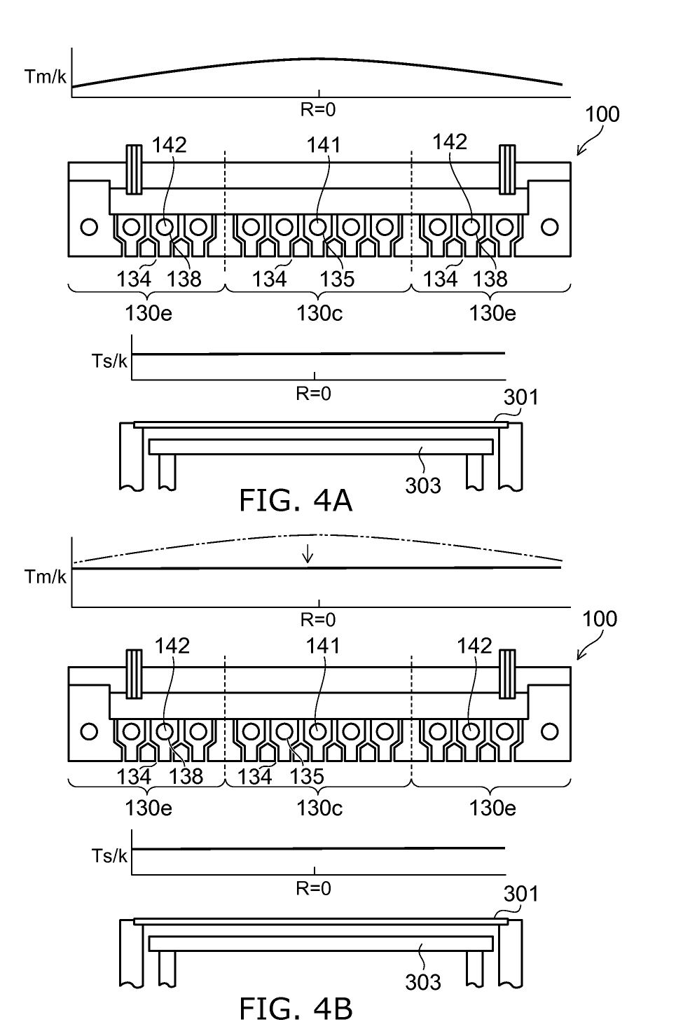

FIG. 4A and FIG. 4B are schematic sectional views showing the operation of the semiconductor manufacturing apparatus of the first embodiment.

In FIG. 4A and FIG. 4B, the temperature distribution of the shower head 100 is shown over the shower head 100. Furthermore, the temperature distribution of the substrate 301 is shown over the substrate 301. Here, a horizontal axis indicates distance from the center (R=0) in a radius direction, and a vertical axis indicates temperature (k).

During the formation of a thin film on the substrate 301, the substrate 301 may be heated to about 1000° C. By this, the shower head 100 receives thermal radiation from the substrate 301. Accordingly, the temperature of the shower head 100 is needed to be reduced by flowing the cooling medium.

For example, in the state shown in FIG. 4A, the temperature of the first cooling medium 141 flowing through the first cooling path 135 and the temperature of the second cooling medium 142 flowing through the second cooling path 138 are set to be the same temperature. This state corresponds to a one path system shower head in which the cooling path is not divided into the first cooling path 135 and the second cooling path 138.

In this case, even if the temperature of the substrate 301 is controlled to be uniform, in the temperature of the shower head 100, the temperature of the center part 130c becomes relatively high. This is because the center part 130c is surrounded by the outer peripheral part 130e, and heat tends to stay in the center part 130c as compared with the outer peripheral part 130e.

When the source gas is introduced into the shower head 100 in the state, the temperature of the gas ejected from the center part 130c becomes different from the temperature of the gas ejected from the outer peripheral part 130e. By this, the growth rate and the film quality of a thin film formed on the substrate 301 become non-uniform in the substrate 301.

In contrast, in the state shown in FIG. 4B, the controller 153 sets the temperature of the first cooling medium 141 to be lower than the temperature of the second cooling medium 142. By this, the temperature of the center part 130c of the shower head 100 is relatively reduced. Accordingly, in the shower head 100, the temperature of the center part 130c becomes substantially equal to the temperature of the outer peripheral part 130e.

In this state, when the source gas is introduced into the shower head 100, the temperature of the gas ejected from the center part 130c and the temperature of the gas ejected from the outer peripheral part 130e become substantially equal to each other. By this, the growth rate and the film quality of a thin film formed on the substrate 301 become substantially uniform in the substrate 301.

Furthermore, in a manufacturing process, layers different in film quality may be laminated on the substrate 301. In this case, source gases forming the respective layers are different from each other. Further, the temperatures of the substrate 301 when the respective layers are formed become different from each other.

For example, in the one path system shower head in which the cooling path is not divided into the first cooling path 135 and the second cooling path 138, there is a case where the temperature distribution control of the shower head can not follow the change of the substrate temperature. For example, when the temperature of the substrate 301 is quickly set to be high temperature from low temperature, in the one path system shower head, the temperature of the center part may overshoot the object temperature. As a result, a long time is taken to reach the object temperature. On the contrary, when the temperature of the substrate 301 is quickly set from high temperature to low temperature, in the one path system shower head, the temperature of the outer peripheral part may undershoot the object temperature.

In contrast, in the semiconductor manufacturing apparatus 200 of the first embodiment, when the temperature of the substrate 301 is quickly set from low temperature to high temperature, the temperature of the center part 130c is previously set to be low. By this, overshoot can be avoided. Furthermore, when the temperature of the substrate 301 is quickly set from high temperature to low temperature, the temperature of the outer peripheral part 130e is previously set to be high. By this, undershoot can be avoided. Furthermore, in the semiconductor manufacturing apparatus 200 of the first embodiment, the temperatures detected by the respective temperature detectors T1 to T5 are transferred to the controller 153. The controller 153 refers to the previously read shower head setting temperature, and can perform feedback control to control the temperature of each of the first cooling medium 141 and the second cooling medium 142 in real time according to the temperatures detected by the respective temperature detectors T1 to T5. By this, when plural constituent layers are formed while the temperature of the substrate 301 is changed to plural set temperatures, the overshoot and the undershoot of the shower head temperature are suppressed, and more stable shower head temperature control can be performed. That is, the semiconductor manufacturing apparatus 200 is excellent in controllability of the temperature of the shower head according to the temperature change of the substrate 301.

### Second Embodiment

In a second embodiment, for example, the shower head 100 is used, and a nitride semiconductor layer is epitaxially grown on the substrate 301. The nitride semiconductor layer is applied to an electric device such as a HEMT (High Electron Mobility Transistor) or an optical device such as an LED (Light Emitting Diode) or an LD (Laser Diode).

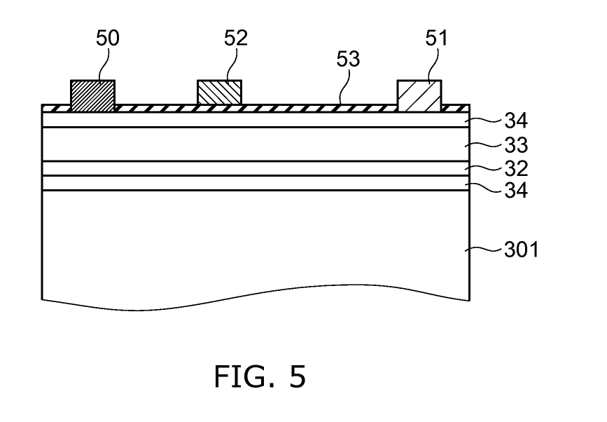

For example, as an example of the electric device, FIG. 5 shows a schematic sectional view of a HEMT.

The substrate 301 includes, for example, silicon (Si). Buffer layers 31 and 32 are provided on the substrate 301 in this order. The buffer layer 31 includes aluminum nitride.

A carrier channel layer 33 is provided on the buffer layer 32. A barrier layer 34 is provided on the carrier channel layer 33. The carrier channel layer 33 includes non-doped gallium nitride (GaN) or non-doped aluminum gallium nitride (Al_{X}Ga_{1-X}N (0≦X<1)). The barrier layer 34 includes non-doped or n-type aluminum gallium nitride (Al_{Y}Ga_{1-Y}N (0<Y≦1, X<Y).

A source electrode 50 and a drain electrode 51 are provided on the barrier layer 34. The source electrode 50 is connected to the barrier layer 34. The drain electrode 51 is separate from the source electrode 50 and is provided on the barrier layer 34. The drain electrode 51 is connected to the barrier layer 34. A gate electrode 52 is provided on the barrier layer 34 through an insulating film 53. The gate electrode 52 is provided between the source electrode 50 and the drain electrode 51.

When the device as stated above is formed, an organic metal gas such as a first organic source gas including gallium (hereinafter, for example, trimethyl gallium (TMG)), a second organic source gas including aluminum (hereinafter, for example, trimethyl aluminum (TMA)), or a third organic source gas including indium (hereinafter, for example, trimethyl indium (TMI)), and a gas including nitrogen (hereinafter, for example, ammonia (NH₃)) are used as source gases. Furthermore, in order to introduce an impurity element into the nitride semiconductor layer, a gas including magnesium or a gas including silicon may be used.

For example, (1) the TMG gas and the NH₃ gas are mixed in the space 110 of the shower head 100, and the mixture gas is ejected to the substrate 301 through the ejection ports 134. The substrate 301 is heated to a specified temperature. By this, a GaN layer including gallium and nitride is formed on the substrate 301. For example, the GaN layer is the carrier channel layer 33 shown in FIG. 5. (2) When a mixture gas including the TMG gas, the TMA gas and the NH₃ gas is used, an AlGaN layer including gallium, aluminum and nitride is formed on the substrate 301. For example, the AlGaN layer is the barrier layer 34 shown in FIG. 5. (3) When a mixture gas including the TMG gas, the TMI gas and the NH₃ gas is used, an InGaN layer including gallium, indium and nitride is formed on the substrate 301. (4) When a mixture gas including the TMG gas, the TMA gas, the TMI gas and the NH₃ gas is used, an InAlGaN layer including gallium, aluminum, indium and nitride is formed on the substrate 301.

At least one of the GaN layer, the AlGaN layer, the InGaN layer and the InAlGaN layer may be formed as a single layer on the substrate 301, or at least two or more of the GaN layer, the AlGaN layer, the InGaN layer and the InAlGaN layer may be laminated. The sequence of the lamination is arbitrary.

For example, in the case of (1), the temperature of the medium flowing through the first cooling path 135 is set to a first temperature (for example, 60° C. to 180° C., preferably 130° C.), and the temperature of the medium flowing through the second cooling path 138 is set to a second temperature higher than the first temperature (for example, 110° C. to 230° C., preferably 180° C.). Here, the temperature of the substrate 301 is, for example, 1000° C. to 1100° C., preferably 1050° C. The pressure in the vacuum chamber 300 is 10 kPa to 40 kPa, preferably 20 kPa. When the film formation rate and the film quality of a material changes according to the temperature of the shower head, the temperatures are controlled as stated above, so that the film formation rate is uniform in the plane of the substrate 301, and the GaN layer having substantially uniform film quality is formed on the substrate 301.

For example, in the case of (2), the temperature of the medium flowing through the first cooling path 135 is set to the first temperature, and the temperature of the medium flowing through the second cooling path 138 is set to a third temperature (for example, 80° C. to 200° C., preferably 150° C.) lower than the second temperature. Here, the temperature of the substrate 301 is, for example, 1000° C. to 1100° C., preferably 1050° C. The pressure in the vacuum chamber 300 is 5 kPa to 30 kPa, preferably 10 kPa. By this, the film formation rate is uniform and the AlGaN layer having substantially uniform film quality is formed on the substrate 301.

When the case of (1) and the case of (2) are combined, a laminate of the GaN layer/AlGaN layer can be formed on the substrate 301. Here, in the case of (2), as compared with the case of (1), the temperature of the outer peripheral part 130e is set to be low.

When the TMG gas, the TMA gas, and the NH₃ gas are mixed, a polymerization reaction proceeds at a relatively low temperature. When a polymer of AlGaN is formed before the mixture gas reaches the substrate 301, the growth rate of the AlGaN layer on the substrate 301 becomes slow.

For example, when the temperature of the outer peripheral part 130e is set to be higher than the temperature of the center part 130c as in the case of (1), the growth rate of the AlGaN layer under the outer peripheral part 130e, that is, in the outer peripheral part of the substrate 301 becomes slow. Thus, in the case of (2), as compared with the case of (1), the temperature of the outer peripheral part 130e is set to be low.

Furthermore, for example, in the case of (3), the temperature of the medium flowing through the first cooling path 135 is set to a temperature (for example, 30° C. to 150° C., preferably 100° C.), and the temperature of the medium flowing through the second cooling path 138 is set to a higher temperature (for example, 50° C. to 170° C., preferably 120° C.). Here, the temperature of the substrate 301 is, for example, 700° C. to 900° C., preferably 800° C. The pressure in the vacuum chamber 300 is 10 kPa to 40 kPa, preferably 20 kPa.

Furthermore, for example, in the case of (4), the temperature of the medium flowing through the first cooling path 135 is set to a temperature (for example, 30° C. to 150° C., preferably 100° C.), and the temperature of the medium flowing through the second cooling path 138 is set to a higher temperature (for example, 60° C. to 180° C., preferably 130° C.). Here, the temperature of the substrate 301 is, for example, 800° C. to 1000° C., preferably 900° C. The pressure in the vacuum chamber 300 is 5 kPa to 30 kPa, preferably 10 kPa.

In the embodiment, the expression of temperature X° C. to temperature Y° C. does not mean only the temperature X and the temperature Y, but includes all temperatures within the range of X° C. or higher and Y° C. or lower.

The term “nitride semiconductor” generally includes semiconductors of all compositions in which composition ratios x, y and z in the chemical formula of BₓIn_{y}Al_{z}Ga_{1-x-y-z}N (0≦x≦1, 0≦y≦1, 0≦z≦1, x+y+z≦1) are changed within the respective ranges. Further, the term “nitride semiconductor” includes semiconductors in which in the chemical formula, a V-group element other than N (nitrogen) is further included, various elements added to control various physical properties such as conductivity are further included, and various unintentionally included elements are further included.

In the embodiments described above, “on” in “A is provided on B” means the case where the A contacts the B and the A is provided on the B and the case where the A does not contact the B and the A is provided above the B. “A is provided on B” may include the case where the A and the B are reversed and the A is located below the B and the case where the A is arranged along with the B. This is because of that the structure of a semiconductor device does not change before/after the rotation even if the semiconductor device of the embodiment is rotated.

Although the embodiments are described above with reference to the specific examples, the embodiments are not limited to these specific examples. That is, design modification appropriately made by a person skilled in the art in regard to the embodiments is within the scope of the embodiments to the extent that the features of the embodiments are included. Components and the disposition, the material, the condition, the shape, and the size or the like included in the specific examples are not limited to illustrations and can be changed appropriately.

The components included in the embodiments described above can be combined to the extent of technical feasibility and the combinations are included in the scope of the embodiments to the extent that the feature of the embodiments is included. Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor manufacturing apparatus comprising:
a cover part;
a gas introduction part provided in the cover part; and
a shower plate including a space, a bottom part, and an outer frame part, the space being provided by jointing the shower plate with the cover part, the space being capable of containing a gas introduced from the gas introduction part, the outer frame part surrounding the bottom part, the bottom part including a plurality of ejection ports to eject the gas, a first cooling path being disposed between the ejection ports and the cover part in a center part of the bottom part, and a second cooling path disposed between the ejection ports and the cover part in an outer peripheral part of the bottom part surrounding the center part, the second cooling path being not connected with the first cooling path.

2. The apparatus according to claim 1, further comprising:
a first supplier capable of supplying a first cooling medium to the first cooling path; and
a second supplier capable of supplying a second cooling medium to the second cooling path.

3. The apparatus according to claim 1, wherein the second cooling path extends to the outer frame part.

4. The apparatus according to claim 1, wherein
a plane shape of the bottom part is circular, and the outer peripheral part and the center part surrounded by the outer peripheral part are concentrically disposed in the bottom part.

5. The apparatus according to claim 1, wherein the first cooling path includes a first portion extending in a second direction crossing a first direction from the bottom part toward the cover part.

6. The apparatus according to claim 5, wherein
the first portion is provided in plural, and
the first portions are connected to each other through first connecting parts.

7. The apparatus according to claim 5, wherein the second cooling path includes:
a second portion extending in the second direction,
a third portion extending in a third direction crossing the first direction and the second direction, and
a fourth portion extending along an outer end of the outer frame part.

8. The apparatus according to claim 7, wherein
the second portion is provided in plural,
the third portion is provided in plural,
the second portions are connected to each other through second connecting parts, and the third portions are connected to each other through third connecting parts.

9. The apparatus according to claim 1, wherein the ejection ports are arranged in a direction in which the first cooling path extends or a direction in which the second cooling path extends.

10. A method for manufacturing a semiconductor device using a semiconductor manufacturing apparatus including a cover part; a gas introduction part provided in the cover part; and a shower plate including a space, a bottom part, and an outer frame part, the space being provided by jointing the shower plate with the cover part, the space being capable of containing a gas introduced from the gas introduction part, the outer frame part surrounding the bottom part, the bottom part including a plurality of ejection ports to eject the gas, a first cooling path being disposed between the ejection ports and the cover part in a center part of the bottom part, and a second cooling path disposed between the ejection ports and the cover part in an outer peripheral part of the bottom part surrounding the center part, the second cooling path being not connected with the first cooling path
the method comprising:
setting a temperature of the first cooling path to a first temperature;
setting a temperature of the second cooling path to a second temperature different from the first temperature;
introducing a first mixture gas to the space, the first mixture gas including a first organic source gas including gallium and a gas including nitrogen; and
forming a nitride semiconductor layer including gallium and nitride on a substrate.

11. The method according to claim 10, wherein the second temperature is higher than the first temperature.

12. The method according to claim 10, wherein
the first mixture gas further includes a second organic source gas including aluminum,
the temperature of the second cooling path is set to a third temperature different from the second temperature, and
the nitride semiconductor layer further includes aluminum.

13. The method according to claim 12, wherein the third temperature is lower than the second temperature.

14. The method according to claim 13, wherein the second temperature is higher than the first temperature.

15. The method according to claim 10, wherein
the first mixture gas further includes a third organic source gas including indium, and
the nitride semiconductor layer further includes indium.

16. The method according to claim 15, wherein the second temperature is higher than the first temperature.

17. The method according to claim 10, wherein
the first mixture gas further includes a second organic source gas including aluminum and a third organic source gas including indium, and
the nitride semiconductor layer further includes aluminum and indium.

18. The method according to claim 17, wherein the second temperature is higher than the first temperature.
